(19) United States
(12) Patent Application Publication
(10) Pub. No.: US 2026/0343858 A1
(43) Pub. Date: Oct. 29, 2026

(54) SEMICONDUCTOR DEVICE AND METHOD OF FABRICATING THEREOF

(71) Applicant: NANYA TECHNOLOGY CORPORATION, New Taipei City (TW)

(72) Inventor: Hsu CHIANG, New Taipei City (TW)

(21) Appl. No.: 19/192,374

(22) Filed: Apr. 29, 2025

(51) Int. Cl. H10B 12/00; H10D 30/63; H10D 62/80

(52) U.S. Cl. CPC H10B 12/33; H10B 12/05; H10B 12/315; H10B 12/485; H10D 30/63; H10D 62/875

(57) ABSTRACT

A semiconductor device, comprising: a first capacitor; a first channel structure over the first capacitor; a first gate dielectric along a sidewall of the first channel structure; a first word line along a sidewall of the first gate dielectric; a bit line over the first channel structure; a second channel structure over the bit line; a second gate dielectric along a sidewall of the second channel structure; a second word line along a sidewall of the second gate dielectric; and a second capacitor over the second channel structure.

### BACKGROUND

Dynamic random-access memory (dynamic RAM or DRAM) is a type of random-access semiconductor memory that stores each bit of data in a memory cell. DRAM is known for its high speed operation, high density, and scalability. However, as the production of DRAM scales up, the manufacturing of DRAM becomes more challenging and more prone to defects. For example, some design may limit the progress of die size shrinkage. Therefore, there is a need for a credible apparatus and fabrication method for a semiconductor device.

### SUMMARY

The disclosure provides a semiconductor device, comprising: a first capacitor; a first channel structure over the first capacitor; a first gate dielectric along a sidewall of the first channel structure; a first word line along a sidewall of the first gate dielectric; a bit line over the first channel structure; a second channel structure over the bit line; a second gate dielectric along a sidewall of the second channel structure; a second word line along a sidewall of the second gate dielectric; and a second capacitor over the second channel structure.

In some embodiments, the second capacitor overlaps, at least in part, the first capacitor.

In some embodiments, the second channel structure overlaps, at least in part, the first channel structure.

In some embodiments, further comprising: a first contact between and electrically connecting the first channel structure and the bit line; and a second contact between and electrically connecting the bit line and the second channel structure.

In some embodiments, further comprising: an first isolation layer adjacent to the first channel structure; and a second isolation layer adjacent to the second channel structure.

In some embodiments, the first gate dielectric is in contact with a sidewall of the first isolation layer, and the second gate dielectric is in contact with a sidewall of the second isolation layer.

In some embodiments, further comprising: a first dielectric layer surrounding the first channel structure, wherein the first word line is between the first dielectric layer and the first isolation layer; and a second dielectric layer surrounding the first channel structure, wherein the second word line is between the second dielectric layer and the second isolation layer.

In some embodiments, in a top view, the first word line and the second word line extend along a first direction, and the bit line extends along a second direction different from the first direction.

In some embodiments, the first channel structure and the second channel structure are made of oxide semiconductor material.

In some embodiments, the first channel structure and the second channel structure are made of indium gallium zinc oxide (IGZO).

The disclosure provides a method of fabricating a semiconductor device, including: forming a first capacitor; forming a first dielectric layer having a first opening over the first capacitor; forming a first word line along a sidewall of the first opening; forming a first gate dielectric along the first word line; forming a first channel structure along the first gate dielectric and over the first capacitor; forming a bit line over the first channel structure; forming a second dielectric layer having a second opening over the first channel structure; forming a second word line along a sidewall of the second opening; forming a second gate dielectric along the second word line; forming a second channel structure along the second gate dielectric and over the first channel structure; and forming a second capacitor over the second channel structure.

In some embodiments, forming the first channel structure comprises: forming a channel material in the first opening over the first dielectric layer; and removing a portion of the channel material, leaving a remaining portion of the channel material as the first channel structure.

In some embodiments, further comprising: forming an isolation layer adjacent to the first channel structure.

In some embodiments, the isolation layer is formed along the first gate dielectric.

In some embodiments, the first word line is between the first dielectric layer and the first isolation layer.

In some embodiments, further comprising: prior to forming the bit line, forming a first contact over the first channel structure, wherein the first contact electrically connects the first channel structure and the bit line; and prior to forming the second channel structure, forming a second contact over the bit line, wherein the second contact electrically connects the bit line and the second channel structure.

In some embodiments, forming the second capacitor comprises: forming a dielectric layer on the second channel structure; forming an opening in the dielectric layer, wherein the opening exposes a top surface of the second channel structure; forming the second capacitor in the opening; and etching back the dielectric layer, wherein a top surface of the dielectric layer is lower than a top surface of the second capacitor.

In some embodiments, the second capacitor is formed overlapping, at least in part, the first capacitor.

In some embodiments, the second channel structure is formed overlapping, at least in part, the first channel structure.

In some embodiments, in a top view, the first word line and the second word line are formed extending along a first direction, and the bit line is formed extending along a second direction different from the first direction.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic view of a semiconductor device, in accordance with some embodiments of the present disclosure.

FIG. 2 is a schematic view of a memory cell, in accordance with some embodiments of the present disclosure.

FIG. 3 is a flow chart of a method of fabricating a semiconductor device, in accordance with some embodiments of the present disclosure.

FIGS. 4A to 22B illustrate a method of fabricating a semiconductor device, in accordance with some embodiments of the present disclosure.

### DETAILED DESCRIPTION

Various example embodiments will be described more fully hereinafter with reference to the accompanying drawings, in which some example embodiments are shown. The present disclosure may, however, be embodied in many different forms and should not be construed as limited to the example embodiments set forth herein. Rather, these example embodiments are provided so that this disclosure will be thorough and complete, and will fully convey the scope of the present disclosure to those skilled in the art. It is noted that, in accordance with the standard practice in the industry, various features are not drawn to scale. In fact, the dimensions of the various features may be arbitrarily increased or reduced for clarity of discussion.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

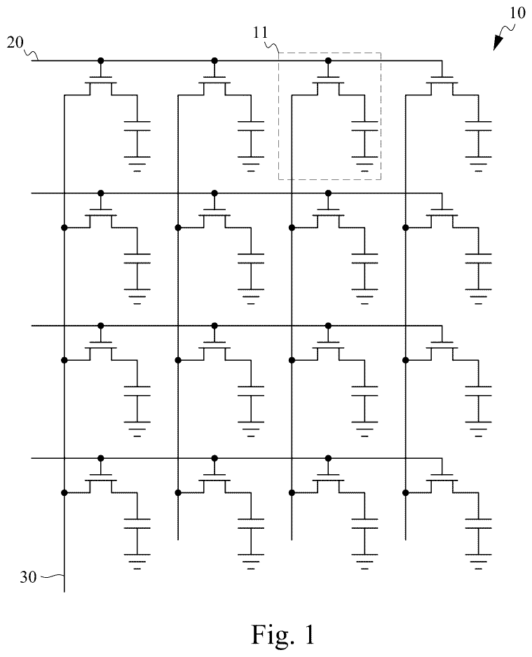

FIG. 1 is a schematic view of a memory array, in accordance with some embodiments of the present disclosure. In some embodiments, the semiconductor device 10 includes multiple memory cells 11 laid out in a rectangular matrix. FIG. 1 shows a simple example with a four-by-four cell matrix. Other memory matrices many be thousands of cells in height and width. In some embodiments, the semiconductor device 10 can be a dynamic random-access memory (dynamic RAM or DRAM).

Each row of memory cells 11 is connected by a word line 20 and each column of memory cells 11 is connected by a bit line 30. A plurality of word lines 20 may extend horizontally. The word lines 20 are parallel to each other. Additionally, the word lines 20 may be spaced apart from each other at substantially equal intervals. On the other side, a plurality of bit lines 30 may extend vertically. Similar to the word lines 20, the bit lines 30 are parallel to each other and may be spaced apart from each other at substantially equal intervals.

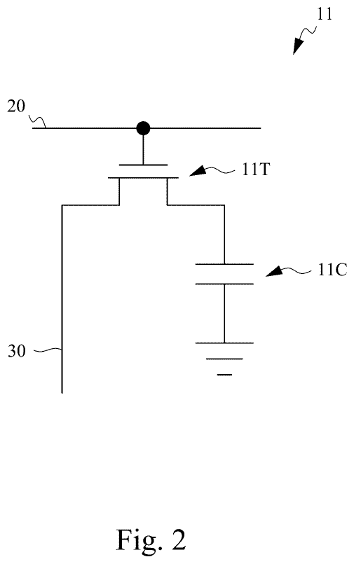

FIG. 2 is a schematic view of a memory cell, in accordance with some embodiments of the present disclosure. Specifically, FIG. 2 is a close-up view of FIG. 1. In some embodiments, a memory cell 11 includes an access transistor 11T and a storage capacitor 11C electrically connected to the access transistor 11T.

In some embodiments, the access transistor 11T is an NMOS transistor, and is configured to control the channel to the memory cell 11 by opening or closing the gate of the access transistor 11T. In some embodiments, the storage capacitor 11C is configured to store information according to the state of electrical charges stored therein. The storage capacitor 11C in an empty state, that is, no charge, is denoted a logic value of 0. The storage capacitor 11C in a fully-charged state is denoted a logic value of 1. The memory cell 11 stores a bit of data by means of the two extreme states of charges stored in the storage capacitor 11C.

In some embodiments, a word line 20 connected to the access transistor 11T is used to control the gate of the access transistor 11T by applying a voltage to the gate of the access transistor 11T. In some embodiments, a bit line 30 is arranged perpendicular to the word line 20 and is also connected to the access transistor 11T. When the gate of the access transistor 11T is turned on, the access transistor 11T connects the storage capacitor 11C to the bit line 30 such that the logic value stored in the storage capacitor 11C will be read on the bit line 30.

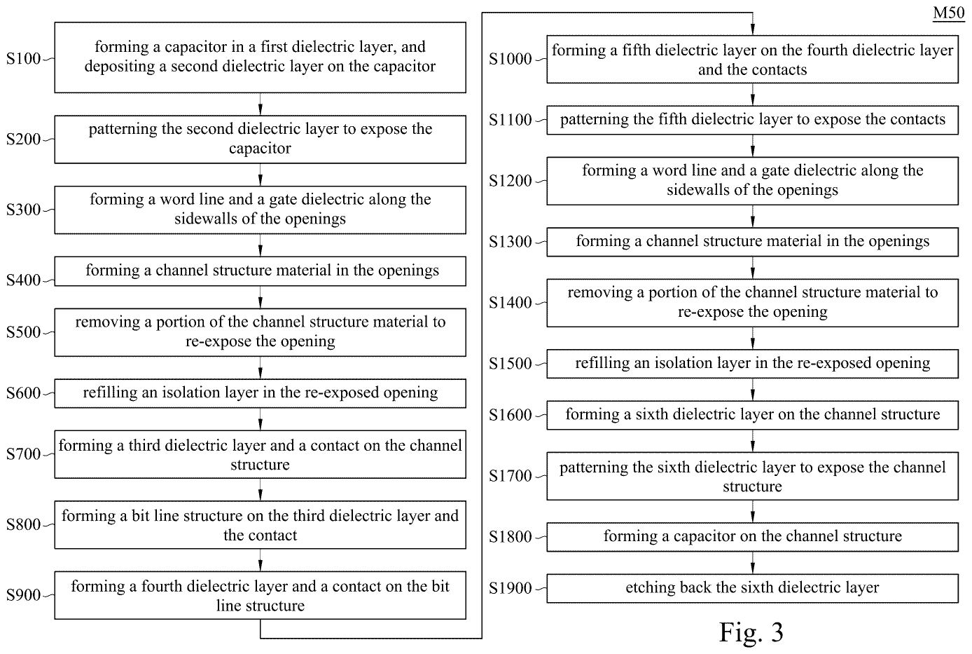

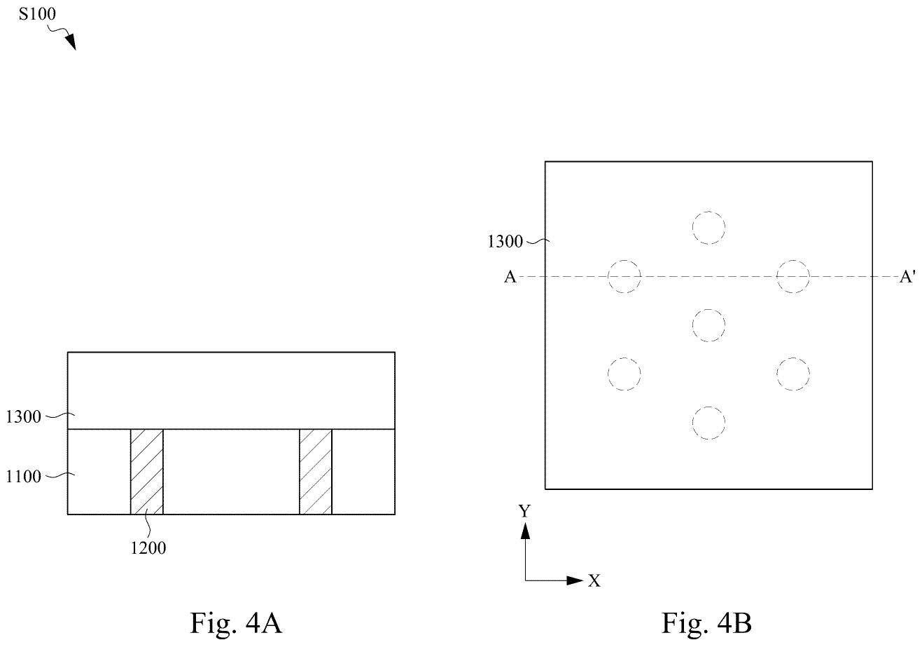

FIG. 3 is a flow chart of a method of fabricating a semiconductor device, in accordance with some embodiments of the present disclosure. FIGS. 4A to 22B illustrate a method of fabricating a semiconductor device, in accordance with some embodiments of the present disclosure. Specifically, FIGS. 4A to 22A are cross-sectional views alone line A-A′ of the top views of FIGS. 4B to 22B, respectively.

The semiconductor device and the fabricating method M50 will be discussed in conjunction with reference to FIGS. 4A to 22B. As illustrated in FIG. 3, a fabricating method M50 may include the following operations S100, S200, S300, S400, S500, S600, S700, S800, S900, S1000, S1100, S1200, S1300, S1400, S1500, S1600, S1700, S1800 and S1900.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

The method M50 starts from operation S100 by forming a capacitor in a first dielectric layer, and depositing a second dielectric layer on the capacitor. Referring to FIG. 4A and FIG. 4B, the first dielectric layer 1100 is deposited on a substrate (not shown), capacitors 1200 are formed in the first dielectric layer 1100, and a second dielectric layer 1300 is deposited on and covering the capacitors 1200.

In some embodiments, the first dielectric layer 1100 is deposited on a substrate (not shown). In some embodiments, the first dielectric layer 1100 is configured to provide an electrical isolation between the capacitors 1200 that will be formed in the subsequent steps. The first dielectric layer 1100 is made of a dielectric material. In some embodiments, the first dielectric layer 1100 is made of oxides such as silicon dioxide (SiO₂).

The first dielectric layer 1100 may be deposited by using chemical vapor deposition (CVD), plasma-enhanced chemical vapor deposition (PECVD), atomic layer deposition (ALD), physical vapor deposition (PVD), low-pressure chemical vapor deposition (LPCVD), flowable chemical vapor deposition (FCVD), or other suitable deposition processes.

In some embodiments, the first dielectric layer 1100 may be patterned to form openings. A mask pattern (not shown) may be formed on the first dielectric layer 1100. Subsequently, the first dielectric layer 1100 is etched through the mask pattern to form openings. In some embodiments, after etching, pieces of the first dielectric layer 1100 may be separated from each other by the openings, in which each opening may extend vertically from the underlying structure in the substrate (not shown) and is parallel to each other. In some embodiments, the openings may be regularly arranged at substantially equal intervals from each other horizontally.

Next, the capacitors 1200 can be formed in the openings. In other words, a capacitor 1200 replaces each opening. In some embodiments, the capacitors 1200 are parallel to each other and may be regularly arranged at substantially equal intervals from each other.

The capacitor 1200 may include a bottom electrode, a capacitor dielectric layer over the bottom electrode, and a top electrode over the capacitor dielectric layer. In some embodiments, the bottom electrode and the top electrode of the capacitor 1200 may include conductive material. In some embodiments, the bottom electrode and the top electrode may include metal. In some embodiments, the bottom electrode and the top electrode may include titanium nitride (TiN). In some embodiments, the capacitor dielectric layer of the capacitor 1200 may include dielectric material. Each of the bottom electrode, capacitor dielectric layer, and top electrode of the capacitor 1200 may be deposited by using CVD, PECVD, ALD, PVD, LPCVD, FCVD or other suitable deposition processes, sequentially.

A planarization process may be performed to the capacitors 1200, so as to level the capacitors 1200 with the first dielectric layer 1100. As a result, the leveled capacitors 1200 are coplanar to the first dielectric layer 1100, therefore share the same top surface. That is, the top surface the leveled capacitor 1200 and the top surface of the first dielectric layer 1100 may be coterminous with each other. A chemical mechanical polishing (CMP) process can be used for the planarization process. The CMP process may stop when the first dielectric layer 1100 is exposed.

Next, the second dielectric layer 1300 may be deposited on the capacitor 1200 and the first dielectric layer 1100. In some embodiments, the second dielectric layer 1300 covers the capacitors 1200. The second dielectric layer 1300 is configured to provide an electrical isolation between some conductive structures (e.g. word line structures) that will be formed in the subsequent steps.

The second dielectric layer 1300 is made of a dielectric material. In some embodiments, the second dielectric layer 1300 and the first dielectric layer 1100 can be made of the same material. In some embodiments, the second dielectric layer 1300 is made of oxides such as silicon dioxide (SiO₂). The second dielectric layer 1300 may be deposited by using CVD, PECVD, ALD, PVD, LPCVD, FCVD, or other suitable deposition processes. In some embodiments, the vertical thickness of the second dielectric layer 1300 may be slightly smaller than that of the first dielectric layer 1100.

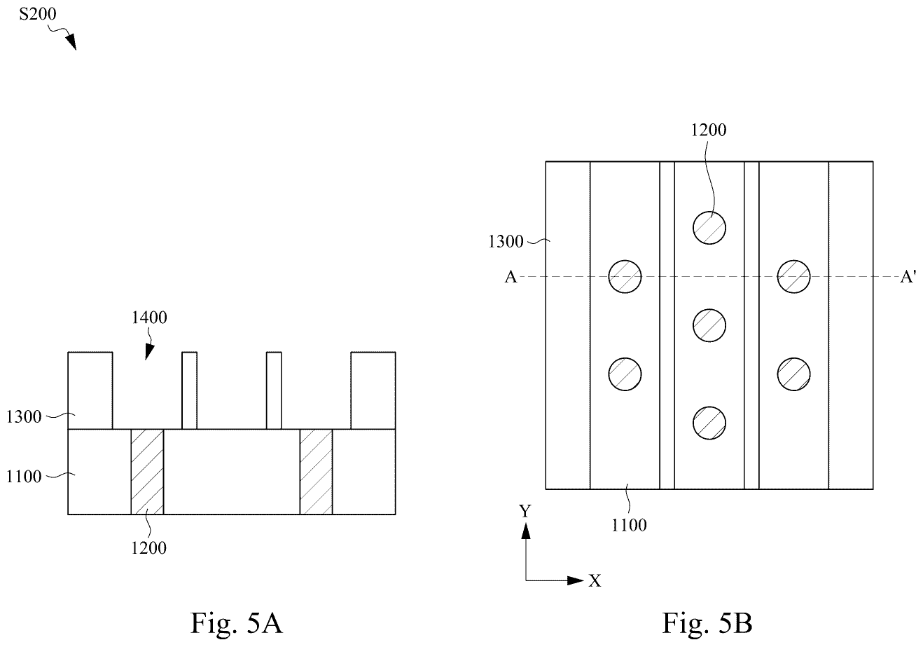

The method M50 proceeds to operation S200 by patterning the second dielectric layer to expose the capacitor. Referring to FIG. 5A and FIG. 5B, the second dielectric layer 1300 may be patterned to form openings 1400 that expose the capacitors 1200. A mask pattern (not shown) may be formed on the second dielectric layer 1300. Subsequently, the second dielectric layer 1300 is etched through the mask pattern.

In some embodiments, operation S200 may include photolithography. In some embodiments, the position of the openings 1400 may be defined by the mask pattern. For example, the mask pattern is formed on vertical portions of the second dielectric layer 1300 on the first dielectric layer 1100 and not overlying the capacitors 1200. Thus, vertical portions of the second dielectric layer 1300 on the first dielectric layer 1100 and not overlying the capacitors 1200 may not be etched during the etching process and the openings 1400 are defined after the etching process. In some embodiments, the openings 1400 have a greater width than the capacitors 1200. In some embodiments, each of the openings 1400 may extend along a first direction (e.g., Y direction), and the openings 1400 are arranged along a second direction (e.g., X direction) different from the first direction and substantially perpendicular to the first direction.

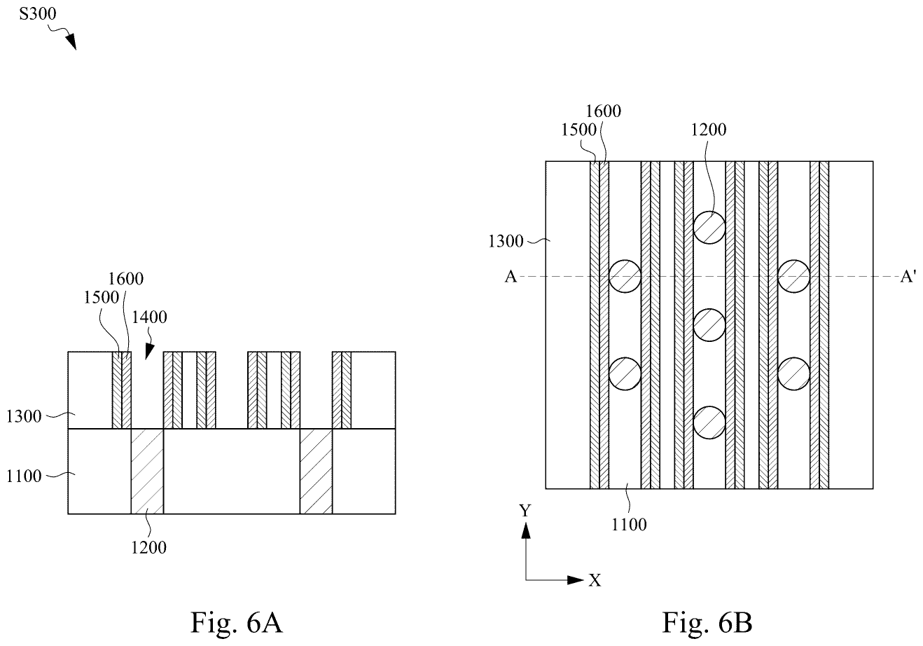

The method M50 proceeds to operation S300 by forming a word line and a gate dielectric along the sidewalls of the openings. Referring to FIG. 6A and FIG. 6B, word lines 1500 and gate dielectrics 1600 are sequentially formed along the sidewalls of the openings 1400.

In some embodiments, a word line material (not shown) may be formed over the underlying structure (e.g., the first dielectric layer 1100, the capacitors 1200, and the second dielectric layer 1300). The word line material may be deposited by using CVD, PECVD, ALD, PVD, LPCVD, FCVD, or other suitable deposition processes. Then, an anisotropic etching process is performed on the word line material to remove the horizontal portions of the word line material, leaving only the vertical portions of the word line material. The remaining vertical portions are referred to as the word lines 1500.

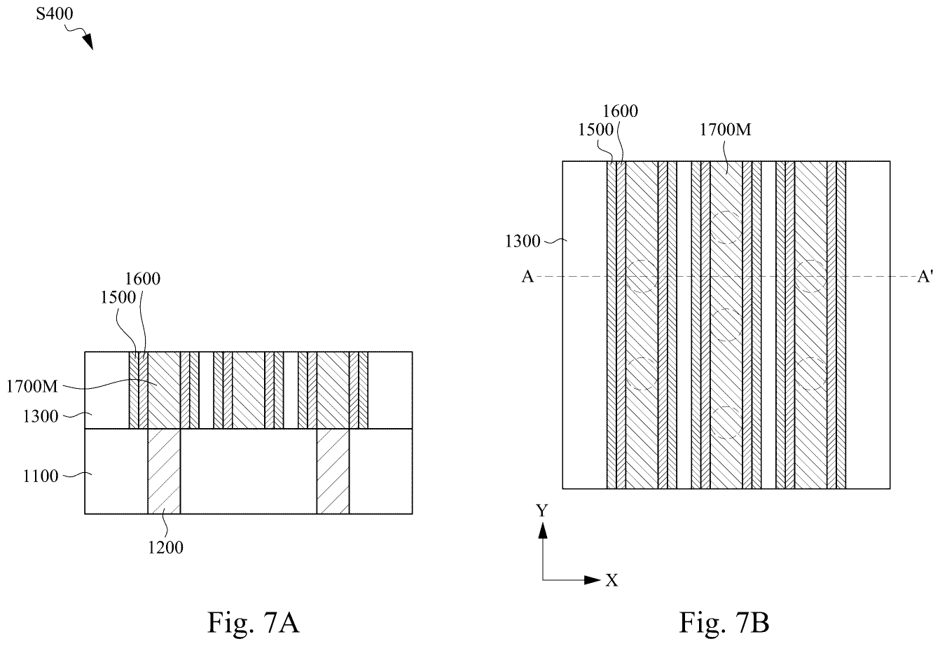

In some embodiments, the word lines 1500 may extend upward from the first dielectric layer 1100 and extends along the sidewalls of the openings 1400. In some embodiments, the word lines 1500 are made of a conductive material. In some embodiments, the word lines 1500 may include metal. In some embodiments, the word lines 1500 may include Tungsten (W). In some embodiments, word lines 1500 can function as a gate electrode to control the channel structures 1700 in FIG. 7A. In some embodiments, the word lines 1500 have a bar-shaped top profile.

Subsequently, gate dielectrics 1600 are formed on the sidewalls of the openings 1400. Specifically, gate dielectrics 1600 extending upward from the first dielectric layer 1100 and extending along the sidewalls of the openings 1400 are formed.

In some embodiments, a gate dielectric material blanket (not shown) may be formed over the underlying structure (e.g., the first dielectric layer 1100, the second dielectric layer 1300, the capacitors 1200, and the word lines 1500). The gate dielectric material blanket may be deposited by using CVD, PECVD, ALD, PVD, LPCVD, FCVD, or other suitable deposition processes.

Then, an anisotropic etching process is performed on the gate dielectric material blanket to remove the horizontal portions of the gate dielectric material blanket, leaving only the vertical portions of the gate dielectric material remaining along sidewalls of the openings 1400. The remaining vertical portions are referred to as the gate dielectrics 1600.

In some embodiments, the gate dielectrics 1600 are made of a dielectric material. In some embodiments, the gate dielectrics 1600 may include silicon oxide (SiO), silicon nitride (SiN), silicon oxynitride (SiON), or the like. In some embodiments, the gate dielectrics 1600 are configured to electrically separate the word lines 1500 and a conductive structure (e.g. a channel structure) that will be formed in the subsequent steps. In some embodiments, the width of the gate dielectrics 1600 is substantially the same as the width of the word lines 1500. In some embodiments, the gate dielectrics 1600 have a bar-shaped top profile.

In some embodiments, the top end of the gate dielectrics 1600 may be substantially leveled with the top surfaces of the second dielectric layer 1300 and the word lines 1500. In some embodiments, the word lines 1500 and the gate dielectrics 1600 do not cover the top end of the capacitors 1200. In other words, the capacitors 1200 remain exposed in the openings 1400.

The method M50 proceeds to operation S400 by forming a channel structure material in the openings. Referring to FIG. 7A and FIG. 7B, a channel structure material 1700M is formed in the openings 1400. Specifically, the channel structure material 1700M is formed on the capacitors 1200 and is surrounded by the gate dielectrics 1600. In some embodiments, the channel structure material 1700M is formed on the first dielectric layer 1100 and is surrounded by the gate dielectrics 1600.

In some embodiments, a channel layer (not shown) may be formed overfilling the openings 1400. The channel layer may be deposited by using CVD, PECVD, ALD, PVD, LPCVD, FCVD, or other suitable deposition processes. Then, a planarization (e.g. a CMP process) may be performed on the channel layer to remove the excess portions of the channel layer on top of the second dielectric layer 1300 as well as to level the channel layer with the second dielectric layer 1300. In some embodiments, the planarization may stop when the second dielectric layer 1300 is exposed. The remaining portion of the channel layer is referred to as the channel structure material 1700M.

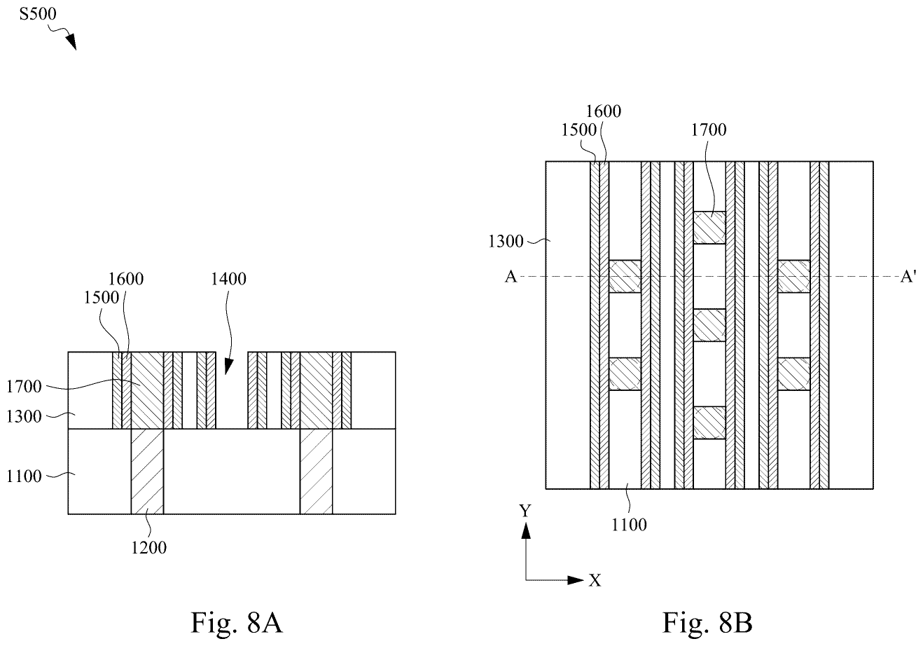

The method M50 proceeds to operation S500 by removing a portion of the channel structure material to re-expose the opening. Referring to FIG. 8A and FIG. 8B, a portion of the channel structure material 1700M not overlying the capacitors 1200 is removed, and the opening 1400 is re-exposed.

First, a mask pattern (not shown) may be formed on the second dielectric layer 1300, the word lines 1500, the gate dielectrics 1600 and the channel structure material 1700M overlying the capacitors 1200. Subsequently, the portion of the channel structure material 1700M not covered by the mask pattern is etched, and the opening 1400 is re-exposed.

The remaining portions of the channel structure material 1700M are referred to as the channel structures 1700. In some embodiments, each of the channel structures 1700 extends vertically from the respective capacitors 1200. In some embodiments, the channel structures 1700 have a vertical length that is substantially the same as the word lines 1500 and/or the gate dielectrics 1600. In some embodiments, the channel structures 1700 may be electrically connected to the underneath capacitors 1200. In some embodiments, the channel structures 1700 have a square-shaped top profile.

In some embodiments, the channel structures 1700 may include an oxide semiconductor (OS) material. In some embodiments, the channel structures 1700 may include indium gallium zinc oxide (IGZO). The vertical channel structures 1700 may improve the memory cell density in the semiconductor device 10.

In some embodiments, the channel structures 1700 may be wrapped by the word lines 1500 through the gate dielectrics 1600. In other words, the word lines 1500 (which may function as a gate electrode), the gate dielectrics 1600, and the channel structures 1700 may form a transistor (e.g., the access transistor 11T of FIG. 2), in which the gate dielectrics 1600 cover the opposite sides of the channel structures 1700. With such configuration, the channel structures 1700 have enlarged contact surface and thus the electric current with the word lines 1500 through the gate dielectrics 1600. Therefore, the word lines 1500 may have a higher speed switching performance and may better control the channel structures 1700 compared to a planar channel structure.

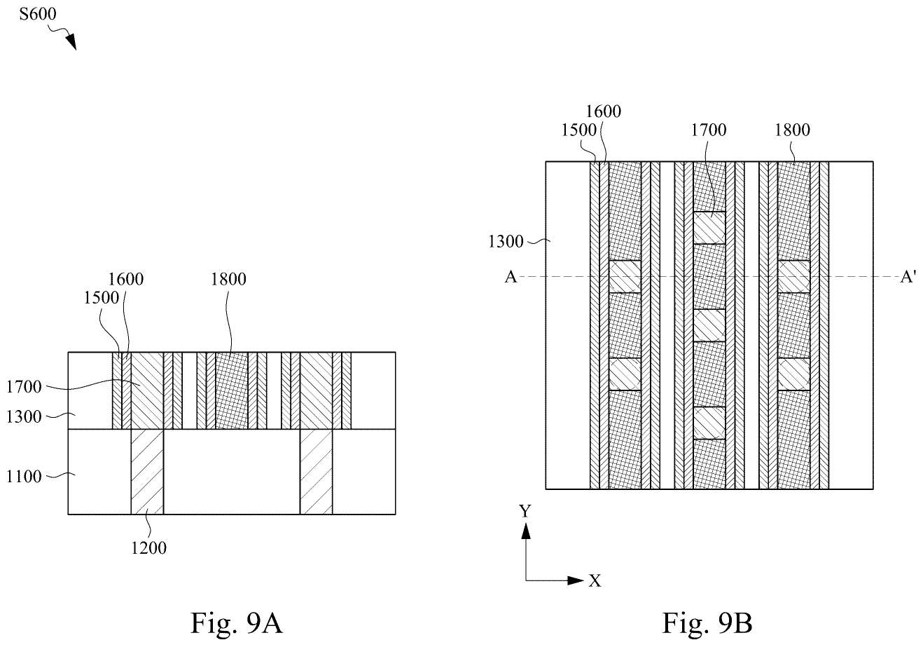

The method M50 proceeds to operation S600 by refilling an isolation layer in the re-exposed opening. Referring to FIG. 9A and FIG. 9B, an isolation layer 1800 is deposited and refilled in the re-exposed openings 1400.

In some embodiments, the isolation layer 1800 may be deposited by using CVD, PECVD, ALD, PVD, LPCVD, FCVD, or other suitable deposition processes. Then, a planarization process, such as CMP, may be performed on the isolation layer 1800 to remove the excess portions of the isolation layer 1800 on top of the second dielectric layer 1300 so as to level the isolation layer 1800 with the second dielectric layer 1300. In some embodiments, the planarization process may stop when the second dielectric layer 1300 is exposed.

In some embodiments, the isolation layer 1800 is made of a dielectric material. In some embodiments, the isolation layer 1800 is made of a dielectric material having a low dielectric constant (low-k) such as silicon oxide (SiO₂) or the like. In some embodiments, the isolation layer 1800 is configured to provide electrical isolation between channel structures 1700.

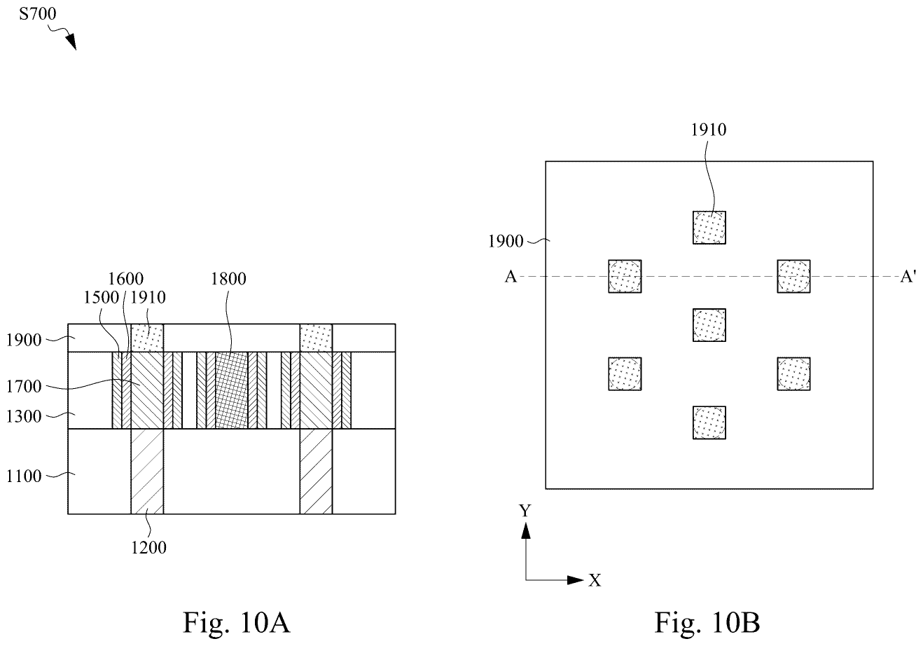

The method M50 proceeds to operation S700 by forming a third dielectric layer and a contact on the channel structure. Referring to FIG. 10A and FIG. 10B, a third dielectric layer 1900 is deposited on the second dielectric layer 1300 and contacts 1910 are formed in the third dielectric layer 1900 and electrically connected to the respective channel structures 1700.

First, the third dielectric layer 1900 is deposited on the second dielectric layer 1300, the word lines 1500, the gate dielectrics 1600, and the isolation layer 1800. In some embodiments, the third dielectric layer 1900 is configured to provide an electrical isolation between the word lines 1500 and a bit line structure that will be formed in the subsequent steps.

The third dielectric layer 1900 is made of a dielectric material. In some embodiments, the third dielectric layer 1900 can be made of the same dielectric material as the first dielectric layer 1100 and/or the second dielectric layer 1300. In some embodiments, the third dielectric layer 1900 is made of oxides such as silicon dioxide (SiO₂). The third dielectric layer 1900 may be deposited by using CVD, PECVD, ALD, PVD, LPCVD, FCVD, or other suitable deposition processes. In some embodiments, the vertical thickness of the third dielectric layer 1900 is smaller than the vertical thickness of the second dielectric layer 1300.

In some embodiments, the third dielectric layer 1900 may be patterned to form openings. A mask pattern (not shown) may be formed on the third dielectric layer 1900. Subsequently, the third dielectric layer 1900 is etched through the mask pattern to form openings (not shown). In some embodiments, the openings expose the channel structures 1700.

Next, the contacts 1910 can be formed in the openings. In other words, a contact 1910 replaces each opening. In some embodiments, the contacts 1910 may be on top of the channel structures 1700.

A planarization process may be performed to the contacts 1910, so as to level the contacts 1910 with the third dielectric layer 1900. As a result, the leveled contacts 1910 may be coplanar to the third dielectric layer 1900, therefore share the same top surface. That is, the top surface the leveled contacts 1910 and the top surface of the third dielectric layer 1900 may be coterminous with each other. A chemical mechanical polishing (CMP) process can be used for the planarization process. The CMP process may stop when the third dielectric layer 1900 is exposed.

In some embodiments, the contacts 1910 are configured to provide an electrical connection between the channel structures 1700 and a bit line structure that will be formed in the subsequent steps. The contacts 1910 are made of a conductive material. The contacts 1910 may be in contact with the channel structures 1700. In some embodiments, the widths of the contacts 1910, the channel structures 1700, and the capacitors 1200 are substantially the same. In some embodiments, the contacts 1910, the channel structures 1700, and the capacitors 1200 substantially align vertically. In some embodiments, the contacts 1910 have a square-shaped top profile.

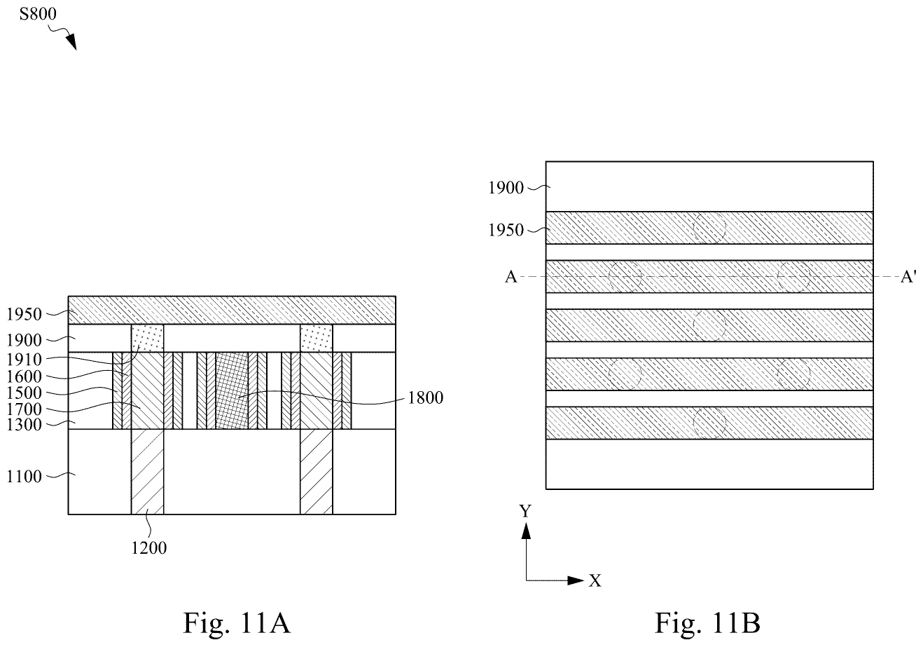

The method M50 proceeds to operation S800 by forming a bit line structure on the third dielectric layer and the contact. Referring to FIG. 11A and FIG. 11B, bit line structures 1950 are formed on the third dielectric layer 1900 and the contacts 1910. In some embodiments, each of the bit line structures 1950 may extend along the second direction (e.g., X direction) that is different from the first direction and substantially perpendicular to the extension direction of word lines 1500.

The bit line structure 1950 may be deposited on the third dielectric layer 1900 and the contacts 1910. The bit line structure 1950 may be deposited by using CVD, PECVD, ALD, PVD, LPCVD, FCVD, or other suitable deposition processes. In some embodiments, the bit line structure 1950 covers the contacts 1910.

In some embodiments, the bit line structure 1950 is made of a conductive material. In some embodiments, the bit line structure 1950 is made of metal. In some embodiments, the bit line structure 1950 may include metal nitride, metal silicide, doped polysilicon, tungsten, tungsten nitride, titanium nitride and/or a combination thereof.

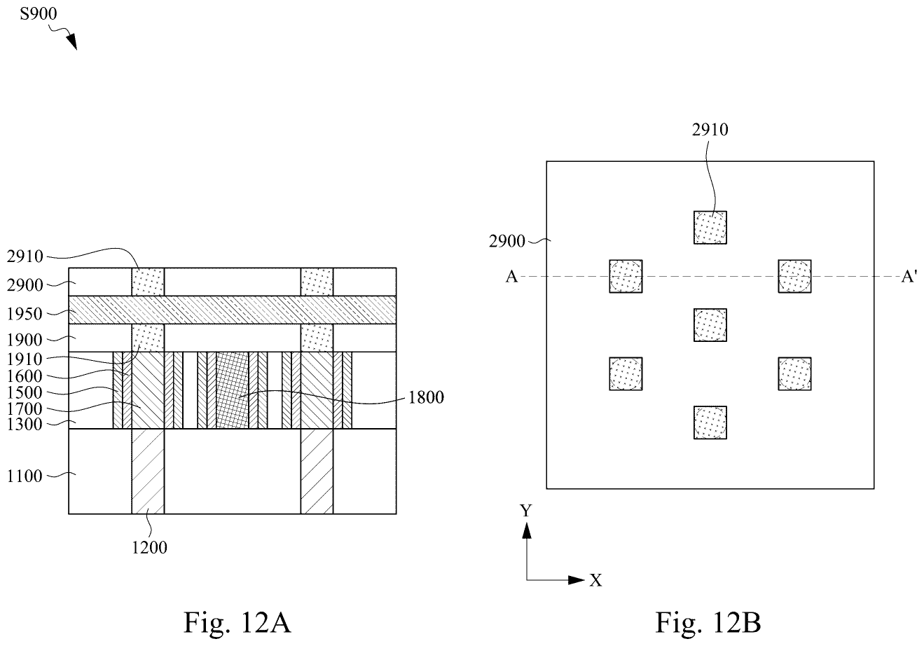

The method M50 proceeds to operation S900 by forming a fourth dielectric layer and a contact on the bit line structure. Referring to FIG. 12A and FIG. 12B, a fourth dielectric layer 2900 and contacts 2910 are formed on the bit line structure 1950. The operation S900 resembles the operation S700, therefore similar elements will be numbered similarly.

First, the fourth dielectric layer 2900 is deposited on the bit line structure 1950. In some embodiments, the fourth dielectric layer 2900 is configured to provide an electrical isolation between underneath bit line structure 1950 and conductive materials that will be formed in the subsequent steps. The fourth dielectric layer 2900 is made of a dielectric material. In some embodiments, the fourth dielectric layer 2900 and the third dielectric layer 1900 include the same material. In some embodiments, the fourth dielectric layer 2900 is made of oxides such as silicon dioxide (SiO₂). The fourth dielectric layer 2900 may be deposited by using CVD, PECVD, ALD, PVD, LPCVD, FCVD, or other suitable deposition processes.

In some embodiments, the fourth dielectric layer 2900 may be patterned to form openings. A mask pattern (not shown) may be formed on the fourth dielectric layer 2900. Subsequently, the fourth dielectric layer 2900 is etched through the mask pattern to form openings (not shown). In some embodiments, the openings are overlying the channel structures 1700 and the contacts 1910.

Next, the contacts 2910 can be formed in the openings. In other words, a contact 2910 replaces each opening. In some embodiments, the contacts 2910 are overlying the channel structures 1700 and the contacts 1910.

A planarization process may be performed to the contacts 2910, so as to level the contacts 2910 with the fourth dielectric layer 2900. As a result, the leveled contacts 2910 may be coplanar to the fourth dielectric layer 2900, therefore share the same top surface. That is, the top surface the leveled contacts 2910 and the top surface of the fourth dielectric layer 2900 may be coterminous with each other. A chemical mechanical polishing (CMP) process can be used for the planarization process. The CMP process may stop when the fourth dielectric layer 2900 is exposed.

In some embodiments, the contacts 2910 have a square-shaped top profile. In some embodiments, the contacts 2910 are configured to provide an electrical connection between the underneath bit line structure 1950 and a channel structure that will be formed in the subsequent steps. The contacts 2910 are made of a conductive material. The contacts 2910 may include the same material as the contacts 1910.

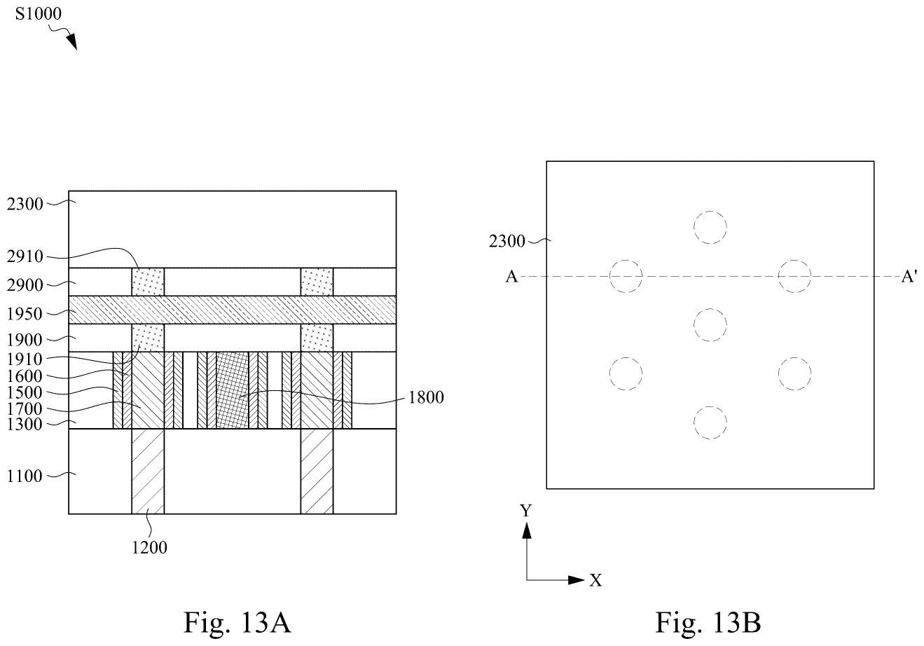

The method M50 proceeds to operation S1000 by forming a fifth dielectric layer on the fourth dielectric layer and the contacts. Referring to FIG. 13A and FIG. 13B, a fifth dielectric layer 2300 is formed on the fourth dielectric layer 2900 and the contacts 2910. The operation S1000 resembles the formation of the second dielectric layer 1300 of operation S100, therefore similar elements will be numbered similarly.

First, the fifth dielectric layer 2300 may be deposited on the fourth dielectric layer 2900 and the contact 2910. The fifth dielectric layer 2300 may be deposited by using CVD, PECVD, ALD, PVD, LPCVD, FCVD, or other suitable deposition processes. In some embodiments, the fifth dielectric layer 2300 covers the contacts 2910. The fifth dielectric layer 2300 is configured to provide an electrical isolation between the contacts 2910 and the conductive structures (e.g. channel structures) that will be formed in the subsequent steps.

The fifth dielectric layer 2300 is made of a dielectric material. In some embodiments, the fifth dielectric layer 2300 and the second dielectric layer 1300 can be made of the same material. In some embodiments, the fifth dielectric layer 2300 is made of oxides such as silicon dioxide (SiO₂). In some embodiments, the vertical thickness of the second dielectric layer 1300 and the fifth dielectric layer 2300 may be substantially the same. In some embodiments, the vertical thickness of the fifth dielectric layer 2300 is greater than the vertical thickness of the fourth dielectric layer 2900.

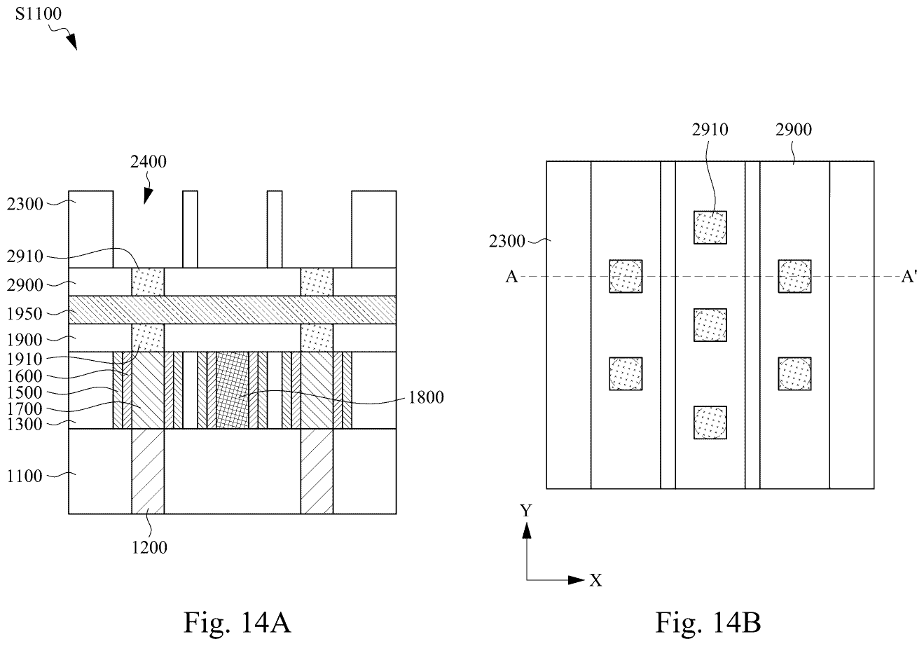

The method M50 proceeds to operation S1100 by patterning the fifth dielectric layer to expose the contacts. Referring to FIG. 14A and FIG. 14B, the fifth dielectric layer 2300 may be patterned to form an opening 2400 that exposes the contacts 2910. The operation S1100 resembles the operation S200, therefore similar elements will be numbered similarly.

First, a mask pattern (not shown) may be formed on the fifth dielectric layer 2300. Subsequently, the fifth dielectric layer 2300 is etched through the mask pattern.

In some embodiments, operation S1100 may include photolithography. In some embodiments, the position of the openings 2400 may be defined by the mask pattern. For example, the mask pattern is formed on portions of the fifth dielectric layer 2300 not overlying and surrounding the contact 2910. Thus, portions of the fifth dielectric layer 2300 not overlying and surrounding the contacts 2910 may not be etched during the etching process and the openings 2400 are defined after the etching process. In some embodiments, the openings 2400 have a greater width than the contacts 2910.

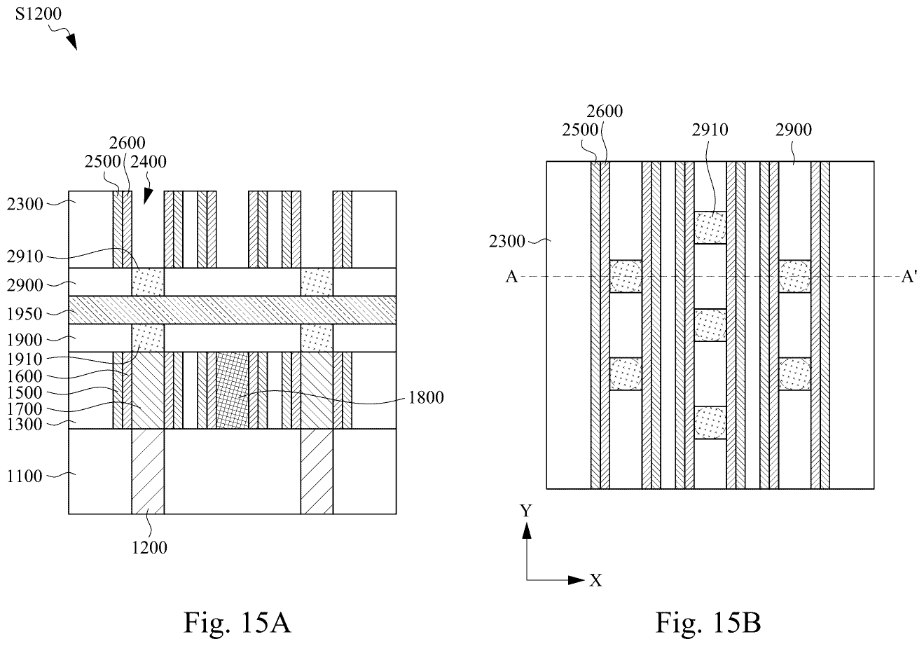

The method M50 proceeds to operation S1200 by forming a word line and a gate dielectric along the sidewalls of the openings. Referring to FIG. 15A and FIG. 15B, word lines 2500 and gate dielectrics 2600 are sequentially formed along the sidewalls of the openings 2400. The operation S1200 resembles the operation S300, therefore similar elements will be numbered similarly.

In some embodiments, a word line material (not shown) may be formed over the underlying structure (e.g., the fifth dielectric layer 2300, the contacts 2910, and the fourth dielectric layer 2900). The word line material may be deposited by using CVD, PECVD, ALD, PVD, LPCVD, FCVD, or other suitable deposition processes. Then, an anisotropic etching process is performed on the word line material to remove the horizontal portions of the word line material, leaving only the vertical portions of the word line material. The remaining vertical portions are referred to as the word lines 2500.

In some embodiments, the word lines 2500 may extend upward from the fourth dielectric layer 2900 and extends along the sidewalls of the opening 2400. In some embodiments, the word lines 2500 are made of a conductive material. In some embodiments, the word lines 2500 may include metal. In some embodiments, the word lines 2500 are made of the same material of the word lines 1500. In some embodiments, the word lines 2500 may include Tungsten (W). In some embodiments, word lines 2500 can function as a gate electrode to control the channel structure that will be formed in the subsequent steps. In some embodiments, word lines 2500 have a bar-shaped top profile.

In some embodiments, the word line 1500 and its overlying word line 2500 may be operable to receive the same control voltage during a write operation.

Subsequently, gate dielectrics 2600 are formed on the sidewalls of the openings 2400. Specifically, gate dielectrics 2600 extending upward from the fourth dielectric layer 2900 and extending along the sidewalls of the openings 2400 are formed.

In some embodiments, a gate dielectric material blanket (not shown) may be formed over the underlying structure (e.g., the fifth dielectric layer 2300, the contacts 2910, and the fourth dielectric layer 2900, and the word lines 1500). The gate dielectric material blanket may be deposited by using CVD, PECVD, ALD, PVD, LPCVD, FCVD, or other suitable deposition processes.

Then, an anisotropic etching process is performed on the gate dielectric material blanket to remove the horizontal portions of the gate dielectric material blanket, leaving only the vertical portions of the gate dielectric material remaining along sidewalls of the openings 2400. The remaining vertical portions are referred to as the gate dielectrics 2600.

In some embodiments, the gate dielectrics 2600 are made of a dielectric material. In some embodiments, the gate dielectrics 2600 are made of the same material as the gate dielectrics 1600. In some embodiments, the gate dielectrics 2600 may include silicon oxide (SiO), silicon nitride (SiN), silicon oxynitride (SiON), or the like. In some embodiments, the gate dielectrics 2600 are configured to electrically separate the word lines 2500 and a conductive structure (e.g. a channel structure) that will be formed in the subsequent steps. In some embodiments, the width of the gate dielectrics 2600 is substantially the same as the width of the word lines 2500. In some embodiments, the gate dielectrics 2600 have a bar-shaped top profile.

In some embodiments, the top end of the gate dielectrics 2600 may be substantially leveled with the top surfaces of the fifth dielectric layer 2300 and the word lines 2500. In some embodiments, the word lines 2500 and the gate dielectrics 2600 do not cover the top end of the contacts 2910. In other words, the contacts 2910 remain exposed in the openings 2400.

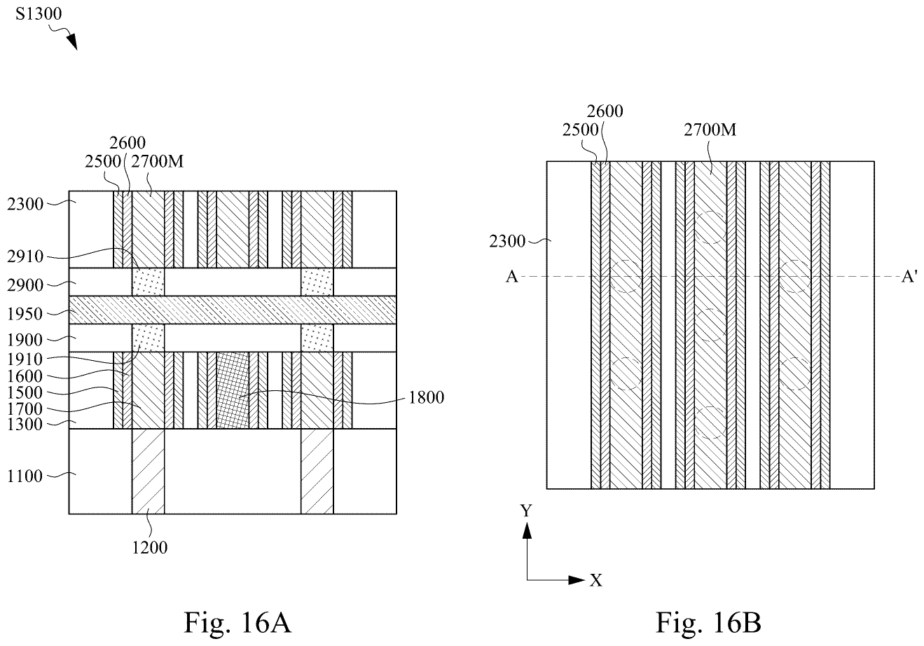

The method M50 proceeds to operation S1300 by forming a channel structure material in the openings. Referring to FIG. 16A and FIG. 16B, a channel structure material 2700M is formed in the openings 1400. Specifically, the channel structure material 2700M is formed on the contacts 2910 and is surrounded by the gate dielectrics 2600. In some embodiments, the channel structure material 2700M is formed on the fifth dielectric layer 2300 and is surrounded by the gate dielectrics 1600. The operation S1300 resembles the operation S400, therefore similar elements will be numbered similarly.

In some embodiments, a channel layer (not shown) may be formed overfilling the openings 2400. The channel layer may be deposited by using CVD, PECVD, ALD, PVD, LPCVD, FCVD, or other suitable deposition processes. Then, a planarization (e.g. a CMP process) may be performed on the channel layer to remove the excess portions of the channel layer on top of the fifth dielectric layer 2300 as well as to level the channel layer with the fifth dielectric layer 2300. In some embodiments, the planarization may stop when the fifth dielectric layer 2300 is exposed. The remaining portion of the channel layer is referred to as the channel structure material 2700M.

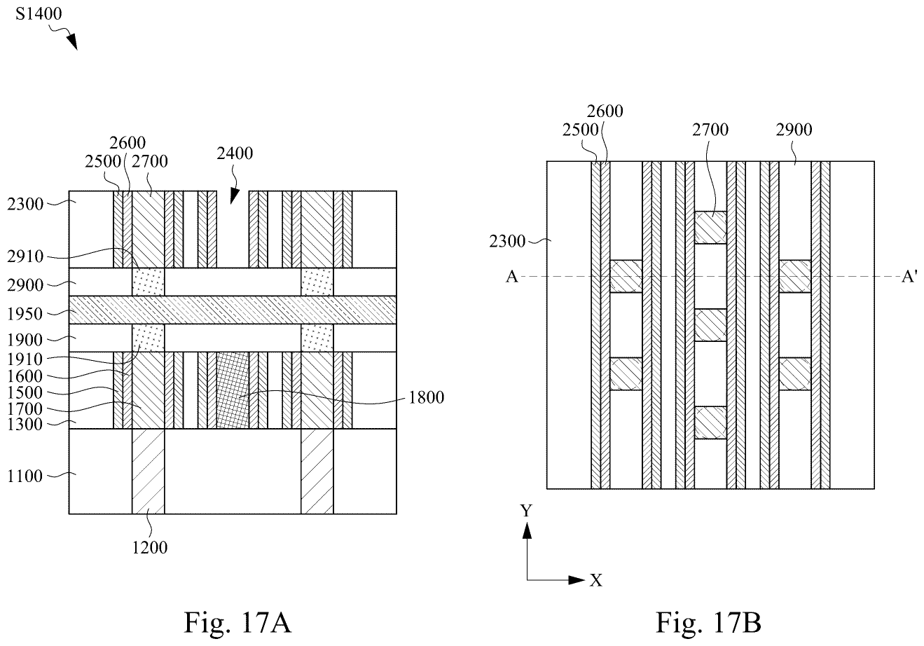

The method M50 proceeds to operation S1400 by removing a portion of the channel structure material to re-expose the opening. Referring to FIG. 17A and FIG. 17B, the portions of the channel structure material 2700M not overlying the contacts 2910 are removed, and the opening 2400 is re-exposed. The operation S1400 resembles the operation S500, therefore similar elements will be numbered similarly.

First, a mask pattern (not shown) may be formed on the fifth dielectric layer 2300, the word lines 2500, the gate dielectrics 2600 and the channel structure material 1700M overlying the contacts 2910. Subsequently, the portion of the channel structure material 2700M not covered by the mask pattern is etched, and the opening 2400 is re-exposed.

The remaining portions of the channel structure material 2700M are referred to as the channel structures 2700. In some embodiments, each of the channel structures 2700 extends vertically from the respective contacts 2910. In some embodiments, the channel structures 2700 have a vertical length that is substantially the same as the word lines 2500 and/or the gate dielectrics 2600. In some embodiments, the channel structures 2700 may be electrically connected to the underneath contacts 2910. In some embodiments, the channel structures 2700 have a square-shaped top profile.

In some embodiments, the channel structures 2700 may be made of the same material as the channel structures 1700. In some embodiments, the channel structures 2700 may include an oxide semiconductor (OS) material. In some embodiments, the channel structures 2700 may include indium gallium zinc oxide (IGZO). The vertical channel structures 2700 may improve the memory cell density in the semiconductor device 10.

In some embodiments, the channel structures 2700 may be wrapped by the word lines 2500 through the gate dielectrics 2600. In other words, the word lines 2500 (which may function as a gate electrode), the gate dielectrics 2600, and the channel structures 2700 may form a transistor (e.g., the access transistor 11T of FIG. 2), in which the gate dielectrics 2600 cover the opposite sides of the channel structures 2700. With such configuration, the channel structures 2700 have enlarged contact surface and thus the electric current with the word lines 2500 through the gate dielectrics 2600. Therefore, the word lines 2500 may have a higher speed switching performance and may better control the channel structures 2700 compared to a planar channel structure.

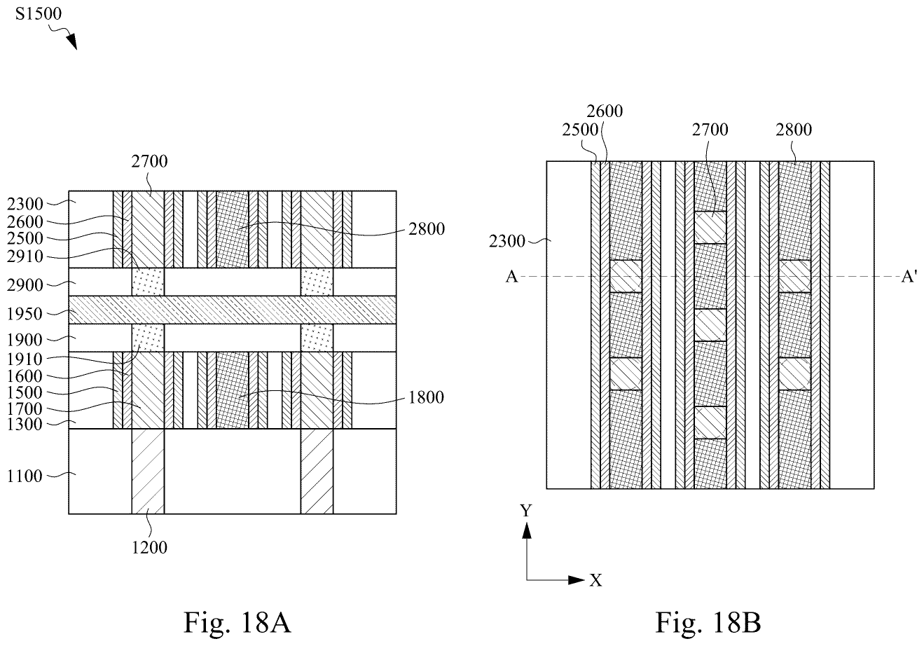

The method M50 proceeds to operation S1500 by refilling an isolation layer in the re-exposed opening. Referring to FIG. 18A and FIG. 18B, an isolation layer 2800 is deposited and refilled in the re-exposed opening 2400. The operation S1500 resembles the operation S600, therefore similar elements will be numbered similarly.

In some embodiments, the isolation layer 2800 may be deposited by using CVD, PECVD, ALD, PVD, LPCVD, FCVD, or other suitable deposition processes. Then, a planarization process, such as CMP, may be performed on the isolation layer 2800 to remove the excess portions of the isolation layer 2800 on top of the fifth dielectric layer 2300 so as to level the isolation layer 2800 with the fifth dielectric layer 2300. In some embodiments, the planarization process may stop when the fifth dielectric layer 2300 is exposed.

In some embodiments, the isolation layer 2800 is made of a dielectric material. In some embodiments, the isolation layer 2800 is made of the same material as the isolation layer 1800. In some embodiments, the isolation layer 2800 is made of a dielectric material having a low dielectric constant (low-k) such as silicon oxide (SiO2) or the like. In some embodiments, the isolation layer 2800 is configured to provide electrical isolation between channel structures 1700.

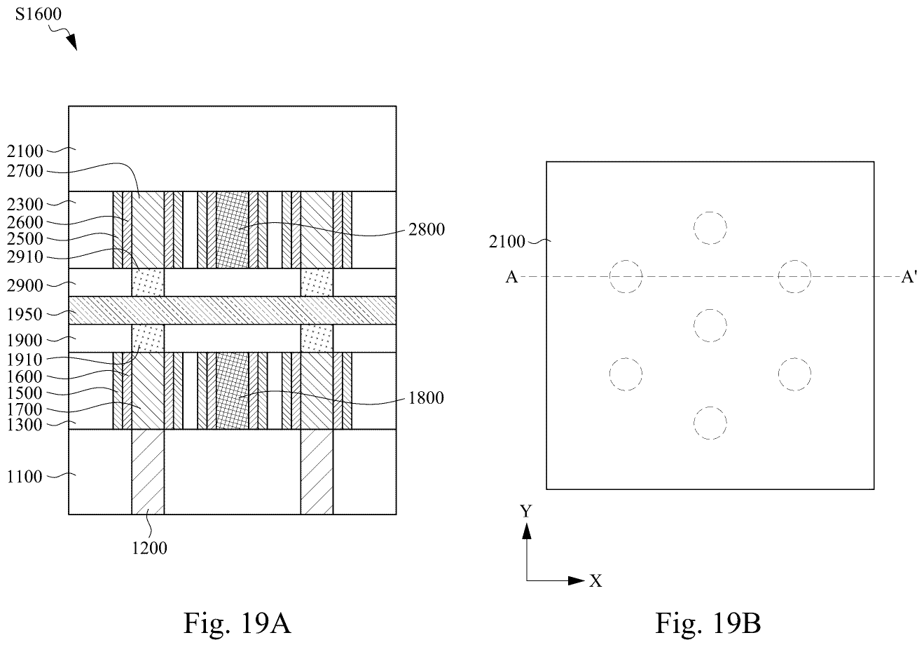

The method M50 proceeds to operation S1600 by forming a sixth dielectric layer on the channel structure. Referring to FIG. 19A and FIG. 19B, a sixth dielectric layer 2100 is deposited on the channel structures 2700.

Specifically, the sixth dielectric layer 2100 is deposited on the channel structures 2700, the fifth dielectric layer 2300, the word lines 2500, the gate dielectrics 2600, and the isolation layer 2800. The sixth dielectric layer 2100 may be deposited by using CVD, PECVD, ALD, PVD, LPCVD, FCVD, or other suitable deposition processes.

The sixth dielectric layer 2100 is made of a dielectric material. The sixth dielectric layer 2100 may be made of a dielectric material different from the dielectric material of the fourth dielectric layer 2900 or the fifth dielectric layer 2300. In some embodiments, the sixth dielectric layer 2100 is made of nitrides such as silicon nitride (SiN).

In some embodiments, the sixth dielectric layer 2100 is configured to provide an electrical isolation between the word lines 2500 and conductive structures that will be formed in the subsequent steps.

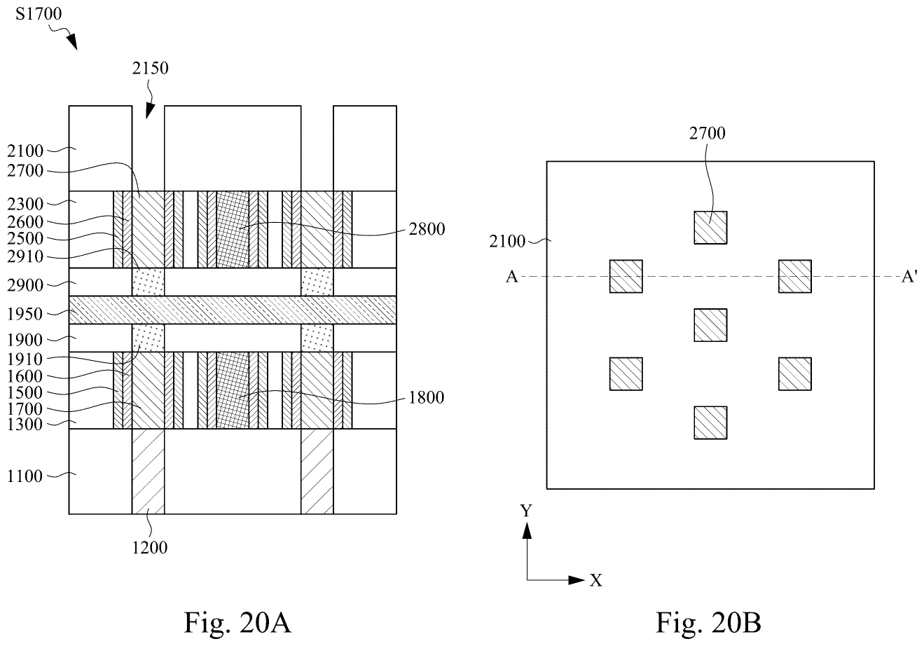

The method M50 proceeds to operation S1700 by patterning the sixth dielectric layer to expose the channel structure. Referring to FIG. 20A and FIG. 20B, the sixth dielectric layer 2100 is patterned to form openings that expose the channel structures 2700.

First, a mask pattern (not shown) may be formed on the sixth dielectric layer 2100. Subsequently, the sixth dielectric layer 2100 is etched through the mask pattern to form openings 2150. In some embodiments, the openings 2150 expose the top surface of the channel structures 2700.

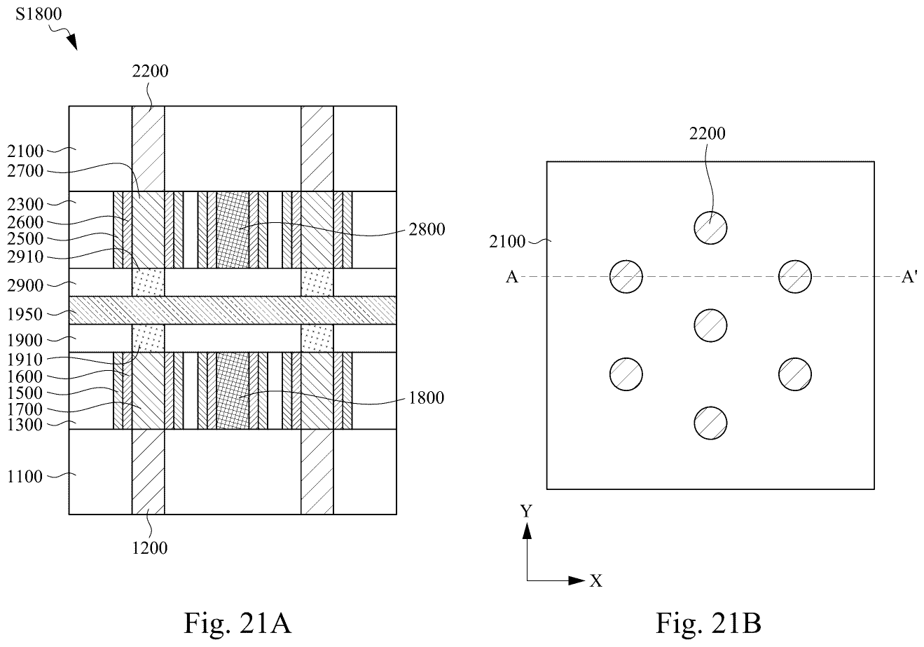

The method M50 proceeds to operation S1800 by forming a capacitor on the channel structure. Referring to FIG. 21A and FIG. 21B, capacitors 2200 are formed on the channel structures 2700.

Specifically, the capacitors 2200 can be formed in the openings 2150. In other words, a capacitor 2200 replaces each opening 2150. In some embodiments, the capacitors 2200 are parallel to each other and may be regularly arranged at substantially equal intervals from each other.

The capacitors 2200 may be substantially the same as the capacitors 1200. That is, the capacitors 2200 may include a bottom electrode, a capacitor dielectric layer over the bottom electrode, and a top electrode over the capacitor dielectric layer. In some embodiments, the bottom electrode and the top electrode of the capacitors 2200 may include conductive material.

The capacitors 2200 may include substantially the same material as the capacitors 1200. In some embodiments, the bottom electrode and the top electrode may include metal. In some embodiments, the bottom electrode and the top electrode may include titanium nitride (TiN). In some embodiments, the capacitor dielectric layer of the capacitors 2200 may include dielectric material. Each of the bottom electrode, capacitor dielectric layer, and top electrode of the capacitors 2200 may be deposited by using CVD, PECVD, ALD, PVD, LPCVD, FCVD or other suitable deposition processes, sequentially.

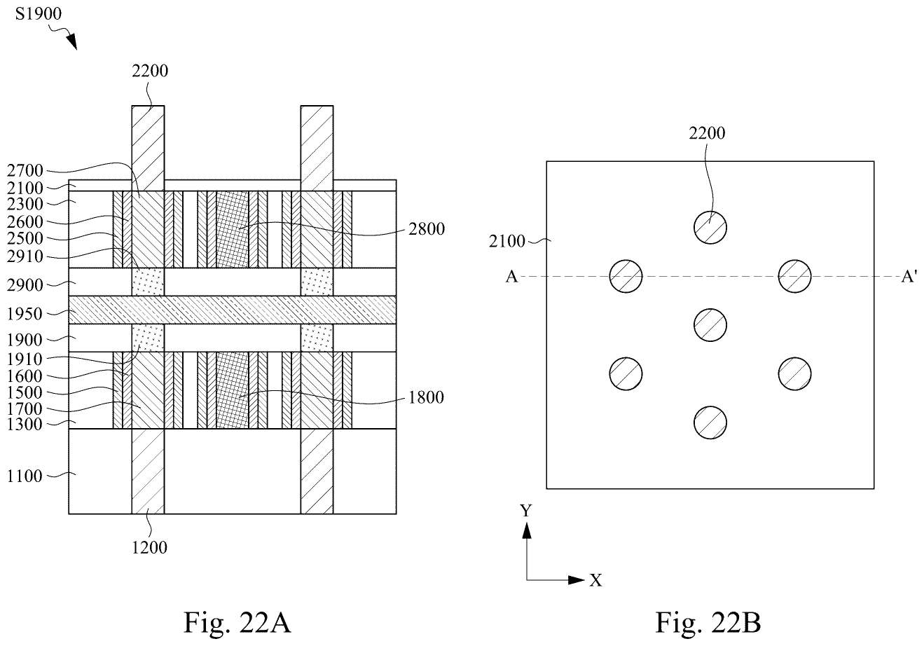

The method M50 proceeds to operation S1900 by etching back the sixth dielectric layer. Referring to FIG. 22A and FIG. 22B, the sixth dielectric layer 2100 is etched back.

First, the sixth dielectric layer 2100 is etched back such that a top surface of the sixth dielectric layer 2100 is lower than a top surface of the capacitors 2200. As a result, the capacitors 2200 may protrude from the top surface of the etched sixth dielectric layer 2100.

In some embodiments, the capacitors 2200 have a vertical thickness greater than that of the sixth dielectric layer 2100. In some embodiments, the sixth dielectric layer 2100 has a vertical thickness smaller than those of the fourth dielectric layer 2900 and/or the fifth dielectric layer 2300.

To sum up, the present disclosure provides a method to fabricate a structure having dual capacitors, dual channel structures, dual gate dielectrics, dual word lines, and dual contacts, with a bit line structure separating each of the dual sets. In some embodiments, each dual set (e.g., capacitors 1200 and capacitors 2200, channel structures 1700 and channel structures 2700, gate dielectrics 1600 and gate dielectrics 2600, word lines 1500 and word lines 2500, contacts 1910 and contacts 2910) overlaps at least in part and have substantially the same dimensions and material.

This dual arrangements design may be beneficial for cell capacitance enlargement (may be enlarged by 2 times) and signal margin enhancement.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor device, comprising:
a first capacitor;
a first channel structure over the first capacitor;
a first gate dielectric along a sidewall of the first channel structure;
a first word line along a sidewall of the first gate dielectric;
a bit line over the first channel structure;
a second channel structure over the bit line;
a second gate dielectric along a sidewall of the second channel structure;
a second word line along a sidewall of the second gate dielectric; and
a second capacitor over the second channel structure.

2. The semiconductor device of claim 1, wherein the second capacitor overlaps, at least in part, the first capacitor.

3. The semiconductor device of claim 1, wherein the second channel structure overlaps, at least in part, the first channel structure.

4. The semiconductor device of claim 1, further comprising:
a first contact between and electrically connecting the first channel structure and the bit line; and
a second contact between and electrically connecting the bit line and the second channel structure.

5. The semiconductor device of claim 1, further comprising:
an first isolation layer adjacent to the first channel structure; and
a second isolation layer adjacent to the second channel structure.

6. The semiconductor device of claim 5, wherein the first gate dielectric is in contact with a sidewall of the first isolation layer, and the second gate dielectric is in contact with a sidewall of the second isolation layer.

7. The semiconductor device of claim 5, further comprising:
a first dielectric layer surrounding the first channel structure, wherein the first word line is between the first dielectric layer and the first isolation layer; and
a second dielectric layer surrounding the first channel structure, wherein the second word line is between the second dielectric layer and the second isolation layer.

8. The semiconductor device of claim 1, wherein in a top view, the first word line and the second word line extend along a first direction, and the bit line extends along a second direction different from the first direction.

9. The semiconductor device of claim 1, wherein the first channel structure and the second channel structure are made of oxide semiconductor material.

10. The semiconductor device of claim 9, wherein the first channel structure and the second channel structure are made of indium gallium zinc oxide (IGZO).

11. A method of fabricating a semiconductor device, comprising:
forming a first capacitor;
forming a first dielectric layer having a first opening over the first capacitor;
forming a first word line along a sidewall of the first opening;
forming a first gate dielectric along the first word line;
forming a first channel structure along the first gate dielectric and over the first capacitor;
forming a bit line over the first channel structure;
forming a second dielectric layer having a second opening over the first channel structure;
forming a second word line along a sidewall of the second opening;
forming a second gate dielectric along the second word line;
forming a second channel structure along the second gate dielectric and over the first channel structure; and
forming a second capacitor over the second channel structure.

12. The method of claim 11, wherein forming the first channel structure comprises:
forming a channel material in the first opening over the first dielectric layer; and
removing a portion of the channel material, leaving a remaining portion of the channel material as the first channel structure.

13. The method of claim 11, further comprising:
forming an isolation layer adjacent to the first channel structure.

14. The method of claim 13, wherein the isolation layer is formed along the first gate dielectric.

15. The method of claim 13, wherein the first word line is between the first dielectric layer and the first isolation layer.

16. The method of claim 11, further comprising:
prior to forming the bit line, forming a first contact over the first channel structure, wherein the first contact electrically connects the first channel structure and the bit line; and
prior to forming the second channel structure, forming a second contact over the bit line, wherein the second contact electrically connects the bit line and the second channel structure.

17. The method of claim 11, wherein forming the second capacitor comprises:
forming a dielectric layer on the second channel structure;
forming an opening in the dielectric layer, wherein the opening exposes a top surface of the second channel structure;
forming the second capacitor in the opening; and
etching back the dielectric layer, wherein a top surface of the dielectric layer is lower than a top surface of the second capacitor.

18. The method of claim 11, wherein the second capacitor is formed overlapping, at least in part, the first capacitor.

19. The method of claim 11, wherein the second channel structure is formed overlapping, at least in part, the first channel structure.

20. The method of claim 11, wherein in a top view, the first word line and the second word line are formed extending along a first direction, and the bit line is formed extending along a second direction different from the first direction.
